(19) United States
(12) Patent Application Publication
(10) Pub. No.: US 2012/0153501 A1
(43) Pub. Date: Jun. 21, 2012

(54) SEMICONDUCTOR DEVICE AND MANUFACTURING METHOD THEREOF

(75) Inventors: Hideya Murai, Tokyo (JP); Kentaro Mori, Tokyo (JP); Shintaro Yamamichi, Tokyo (JP); Masahiro Komuro, Kanagawa (JP); Masaya Kawano, Kanagawa (JP)

(73) Assignees: RENESAS ELECTRONICS CORPORATION, Kawasaki-shi, Kanagawa (JP); NEC CORPORATION, Minato-ku, Tokyo (JP)

(21) Appl. No.: 13/392,714

(22) PCT Filed: Aug. 27, 2010
(86) PCT No.: PCT/JP2010/064562

§ 371 Date: Feb. 27, 2012

(30) Foreign Application Priority Data
Aug. 28, 2009 (JP) 2009-198268

(51) Int. Cl. H01L 23/538; H01L 21/56

(52) U.S. Cl. 257/774; 438/127; 257/E23.174; 257/E21.502

(57) ABSTRACT

In a semiconductor device in which the semiconductor chip including the external terminal(s) is embedded in an insulating layer and interconnect conductor(s) is (are) formed on the insulating layer, base hole(s) is (are) formed at position(s) of the insulating layer corresponding to the external terminal(s) in a state where the semiconductor chip has shrunk after having been embedded in the insulating layer. The interconnect conductor(s) is (are) electrically connected to the external terminal(s) through the base hole(s).

### DESCRIPTION OF RELATED APPLICATION

The present invention is based upon and claims the benefit of the priority of Japanese Patent Application No. 2009-198268 (filed on Aug. 28, 2009), the disclosure of which is incorporated herein in its entirety by reference.

### TECHNICAL FIELD

The present invention relates to a semiconductor device and a manufacturing method of the semiconductor device in which a semiconductor chip is embedded into an insulating layer, and interconnect conductor(s) is (are) formed on the insulating layer. More specifically, the invention relates to a semiconductor device and a manufacturing method of the semiconductor device in which the number of external terminal(s) is large and pitches of the external terminal(s) is (are) narrow.

### BACKGROUND

In recent years, a semiconductor device referred to as an “embedded chip substrate” or the like and a semiconductor device in each of which an insulating resin layer and an interconnect layer are formed over semiconductor chips are drawing attention. In the “embedded chip substrate”, a semiconductor chip or the like obtained by separation into individual chips is embedded in the insulating layer such as a resin substrate or the like. In these semiconductor devices, for example, the chips that have been collectively formed on a wafer are separated into individual chips by dicing or the like, each individual chip is mounted on a support substrate, the insulating layer and the interconnect layer made of metal are formed over the support substrate including the individual chip, and external lead-out pads are formed.

As such a semiconductor device, Patent Document 1, for example, discloses a ball grid array package (related art 1; refer to FIG. 5). In this package, a base surface of an IC chip 103 is joined to a metal heat dissipation plate 101 using a metal paste 102, and a plurality of insulating layer resin layers 104a, 104b and 104c are formed around and over the IC chip 103 joined to the metal heat dissipation plate 101. A mounting pad 131 of the IC chip 103 is joined to an interconnect conductor 107 formed in a through hole of the insulating layer resin layer 104a by plating. The insulating layer resin layer 104a is a lowermost one of the insulating layer resin layers 104a, 104b, and 104C on the page of FIG. 5. The mounting pad 131 is connected to a BGA mounting pad 108 formed on a surface of the insulating layer resin layer 104c, which is an uppermost one of the insulating resin layers 104a, 104b, and 104c, through the interconnect conductor 107 formed on a surface of the insulating layer resin layer 104b and in a through hole. A BGA solder bump 109 is formed on each BGA mounting pad 108.

Patent Document 2 discloses a manufacturing method of a multi-layer printed circuit board. In this multi-layer printed circuit board, conductor circuits 258 and 259 and inter-layer resin insulating layers 250 and 251 are repetitively formed over a core substrate 230, and via holes 260 and 261 are respectively formed in the inter-layer resin insulating layers 250 and 251 to make electrical connection through the via holes 260 and 261. The manufacturing method comprises: (a) holding an IC chip 220 in the core substrate 230; (b) forming positioning marks 231 on the core substrate 230 based on positioning marks 223 of the IC chip 220; and (c) performing a process or formation based on the positioning marks 231 on the core substrate 230 (related art 2; refer to FIG. 6).
[Patent Document 1]
JP Patent Kokai Publication No. JP2001-15650A
[Patent Document 2]
JP Patent Kokai Publication No. JP2001-332863A

### SUMMARY

The entire disclosure of each of Patent Documents 1 and 2 listed above is incorporated herein by reference. The following analysis is given by the present invention.

Each of the techniques described in Patent Documents 1 and 2 listed above, however, has the following problem.

In the technique described in Patent Document 1, the IC chip is mounted on the metal support plate, and is then embedded in the insulating layer resin layers. Interconnect conductors are then formed. The metal support plate and each insulating layer resin layer have different heat expansion coefficients, and a resin associated with the insulating layer resin layers shrinks when cured. After the resin has been cured, the IC chip shrinks, so that the position of each IC-side mounting pad changes on the IC chip. For that reason, even if the IC chip has been mounted at an accurate position on the metal support plate, the position of the IC-side mounting pad on the IC chip may not be aligned with positions of the via and/or the interconnect conductor(s) on the overlying layers. That is, even if the mounting accuracy of the IC chip is increased, the position of the IC-side mounting pad deviates due to shrinkage of the IC chip. Thus, there is a limit to aligning the positions of the IC-side mounting pad and the via. When the resin associated with the insulting layer resin layers is opaque, this positional misalignment cannot be identified even if the position of the via is observed from above. Accordingly, this positional misalignment becomes a problem in particular. While shrinkage of the semiconductor chip due to the embedding is problematic in individual semiconductor devices, the semiconductor chip shrinkage is problematic in particular when a large support substrate is used and a large number of semiconductor chips are mounted on the support substrate in a manufacturing process to simultaneously manufacture a large number of semiconductor devices.

Preferably, when producing a semiconductor device where a semiconductor chip or the like is embedded in an insulating layer such as a resin substrate, a plurality of chips are mounted on a support plate, the insulating layer is formed over the plurality of semiconductor chips at a time (in a lump), and vias and interconnects are formed in order to improve productivity. As a method of forming the interconnects for the plurality of semiconductor chips at a time, the following method, for example, can be used: after the semiconductor chips have been embedded in the insulating layer, the vias are formed by a laser or the like, a plating resist connected to the vias is formed on the insulating layer, exposure in a lump is performed, using a mask extending over a plurality of semiconductor chip regions. Then, development is performed to form the interconnects by plating. That is, in the semiconductor device including such a large support substrate, via positions are not set for each semiconductor chip. The semiconductor chips are mounted based on reference points for an entirety of the substrate, and then the vias and the interconnects are formed. For that reason, positional deviation of pads caused by shrinkage of the semiconductor chips becomes a problem in particular. In other words, during a process of simultaneously forming the interconnects for the plurality of semiconductor chips, no problem arises when the external terminal size of each semiconductor chip is sufficiently large compared with a positional deviation of an external terminal (pad) caused by the shrinkage of the semiconductor chip. However, when the external terminal size of the semiconductor chip is small as in the case of LSI (Large Scale Integration), a formed interconnect will come off from a corresponding one of the external terminal(s) of the semiconductor chip. Then, a conduction failure or deterioration of reliability may be thereby caused. Provision of a large pad for an interconnect end may be considered so as to absorb a positional deviation of the external terminal mounted on the chip. In this case, however, there is a problem that connection between pads at fine pitches and/or routing of a lot of interconnects between pads becomes difficult. In recent years in particular, performance of semiconductor chips has increasingly become higher, the number of external terminal(s) of each semiconductor chip has increased, a pitch between the external terminal(s) has been increasingly narrowed, so that interconnect formation by an exposure in lump or the like in the semiconductor device of the type with the chip embedded therein has increasingly become difficult.

In the technique described in Patent Document 2, the positioning marks are formed on the core substrate, based on the positioning marks of each IC chip. Shrinkage of the IC chip is not taken into consideration. Thus, a similar problem to that described above may occur due to the shrinkage of the chip. In the technique described in Patent Document 2, no consideration is taken into pad position deviations that may occur due to chip shrinkage when a plurality of chips are mounted. Accordingly, there is also a problem that position(s) of each pad and a corresponding one of vias are not aligned after chip shrinkage.

A major challenge of the present invention is to provide a semiconductor device and a manufacturing method of the semiconductor device with a high yield and excellent reliability, which can be applied to a semiconductor chip including a large number of narrow-pitched terminals, as well.

According to a first aspect of the present invention, in a semiconductor device with a semiconductor chip embedded in an insulating layer thereof and with interconnect conductor(s) formed on the insulating layer thereof, the semiconductor chip including external terminal(s), base hole(s) is (are) formed at position(s) of the insulating layer corresponding to the external terminal(s) in a state where the semiconductor chip has shrunk after having been embedded in the insulating layer; and the interconnect conductor(s) is (are) electrically connected to the external terminal(s) through the base hole(s).

Preferably, in the semiconductor device of the present invention, the interconnect conductor(s) is (are) formed to correspond to the external terminal(s) in the state where the semiconductor chip has shrunk after having been embedded in the insulating layer, and are electrically connected to the external terminal(s) through via interconnect(s) embedded in the base hole(s).

Preferably, in the semiconductor device of the present invention, the interconnect conductor(s) is (are) formed to correspond to the external terminal(s) in the state where the semiconductor chip has shrunk after having been embedded in the insulating layer, and are directly connected to the external terminal(s) through the base hole(s).

Preferably, in the semiconductor device of the present invention, the semiconductor chip has a thickness of 50 μm or less.

Preferably, in the semiconductor device of the present invention, the semiconductor chip is mounted on a support plate; and the insulating layer is formed over the support plate including the semiconductor chip, thereby embedding the semiconductor chip therein.

Preferably, in the semiconductor device of the present invention, the support plate is a metal plate.

Preferably, in the semiconductor device of the present invention, the semiconductor chip has a thickness thinner than the support plate.

Preferably, in the semiconductor device of the present invention, the insulating layer is formed of a resin.

Preferably, in the semiconductor device of the present invention, the resin is a thermosetting resin.

Preferably, in the semiconductor device of the present invention, the semiconductor chip comprises a plurality of semiconductor chips.

Preferably, in the semiconductor device of the present invention, the support plate has a heat expansion coefficient larger than that of the semiconductor chip.

Preferably, in the semiconductor device of the present invention, the insulating layer has a heat expansion coefficient larger than that of the semiconductor chip.

According to a second aspect of the present invention, in a method of manufacturing a semiconductor device with a semiconductor chip embedded in an insulating layer thereof and with interconnect conductor(s) formed on the insulating layer thereof, the semiconductor chip including external terminal(s), the method comprising: after embedding a semiconductor chip in the insulating layer, forming base hole(s) leading to the external terminal(s) at position(s) of the insulating layer that have been corrected to correspond to the external terminal(s) in a state where the semiconductor chip has shrunk.

Preferably, the method of manufacturing a semiconductor device of the present invention comprises: after forming the base hole(s), embedding [via interconnect] conductors in the base hole(s); and forming on the insulating layer including the via interconnect(s) the interconnect conductor(s) that has (have) been corrected to correspond to the external terminal(s) in the state where the semiconductor chip has shrunk.

Preferably, the method of manufacturing a semiconductor device of the present invention comprises: after forming the base hole(s), forming on the insulating layer including the base hole(s) and the external terminal(s) the interconnect conductor(s) that has (have) been corrected to correspond to the external terminal(s) in the state where the semiconductor chip has shrunk.

Preferably, the method of manufacturing a semiconductor device of the present invention comprises: before forming the base hole(s), mounting the semiconductor chip on a support plate; and forming the insulating layer over the support plate including the semiconductor chip after mounting the semiconductor chip, thereby embedding the semiconductor chip in the insulating layer.

Preferably, the method of manufacturing a semiconductor device of the present invention comprises: removing the support plate after forming the interconnect conductor(s).

According to the present invention, after the semiconductor chip has been embedded in the insulating layer, the base hole(s) leading to the external terminal(s) is (are) formed at position(s) of the insulating layer corresponding to the external terminal(s) in the state where the semiconductor chip has shrunk. A problem of positional misalignment between the external terminal(s) and the base hole(s) is (are) thereby solved even if the semiconductor chip has shrunk. Accordingly, there can be obtained a semiconductor-chip-embedded type semiconductor device with a high yield and excellent reliability, in which pitches at which external terminal(s) connected to a semiconductor chip can be narrowed, and the semiconductor chip having a large number of the narrow-pitched external terminal(s) can also be embedded with high productivity. Further, according to the present invention, the semiconductor chip greatly shrinks in each of the following cases: when the insulating layer with the semiconductor chip embedded therein is opaque; when the semiconductor chip is thinned to 50 μm or less; when the semiconductor chip is mounted on the support plate; when the semiconductor chip is thinner than the support plate; when the insulating layer is a thermosetting resin; when the plurality of the semiconductor chips are mounted on the support plate; and when the support plate has a heat expansion coefficient larger than that of the semiconductor chip. In these cases, the effect of the present invention is especially great.

### BRIEF DESCRIPTION OF THE DRAWINGS

FIG. 1 is a sectional view schematically showing a configuration of a semiconductor device according to a first example of the present invention;

FIG. 2 is a sectional view schematically showing a configuration of a variant of the semiconductor device according to the first example of the present invention;

FIGS. 3A to 3D are sectional views of a first process schematically showing a method of manufacturing the variant of the semiconductor device according to the first example of the present invention;

FIGS. 4A to 4C is sectional views of a second process schematically showing a method of manufacturing the variant of the semiconductor device according to the first example of the present invention;

FIG. 5 is a sectional view schematically showing a configuration of a semiconductor device (ball grid array package) according to related art example 1;

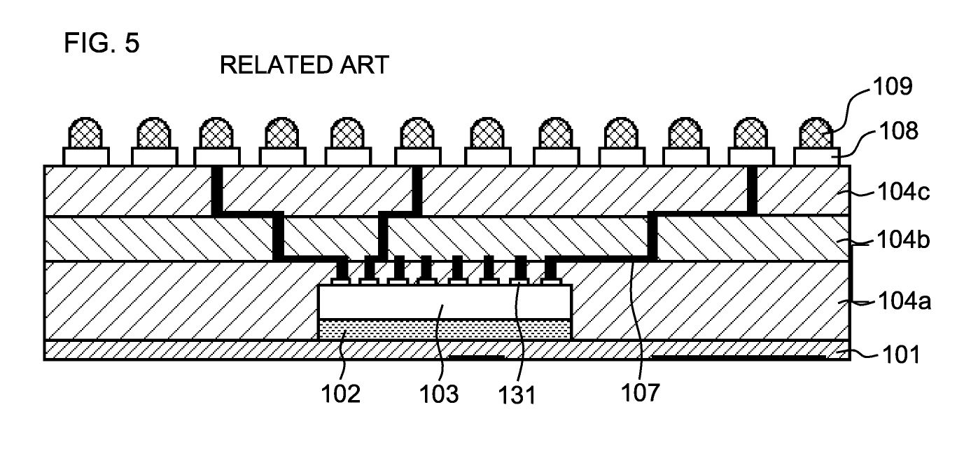

FIG. 6 is a sectional view schematically showing a configuration of a semiconductor device (multi-layer printed circuit board) according to related art example 2; and

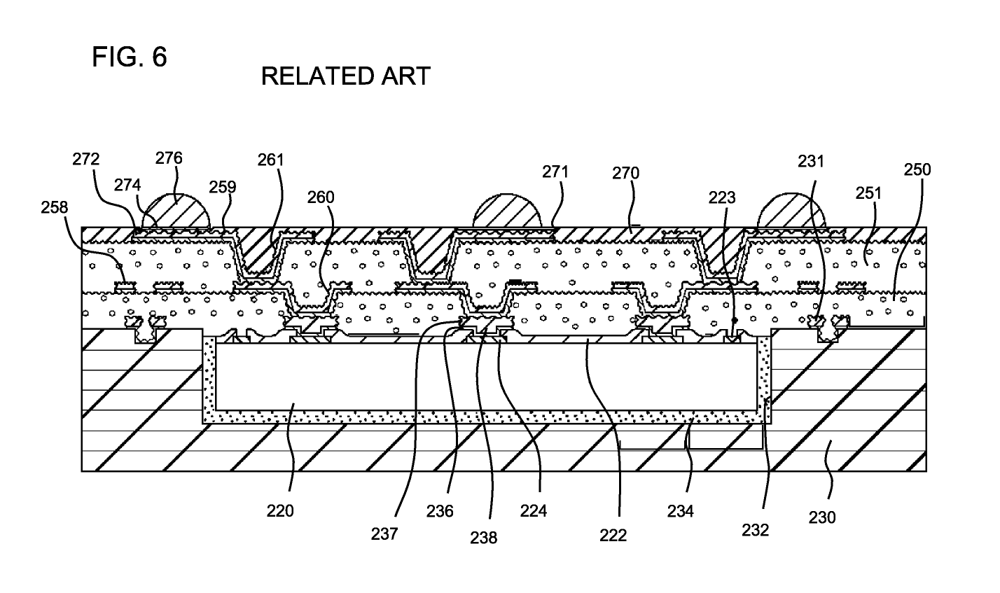

FIG. 7 is a sectional view schematically showing a configuration of a semiconductor device according to related art example 3.

### PREFERRED MODES

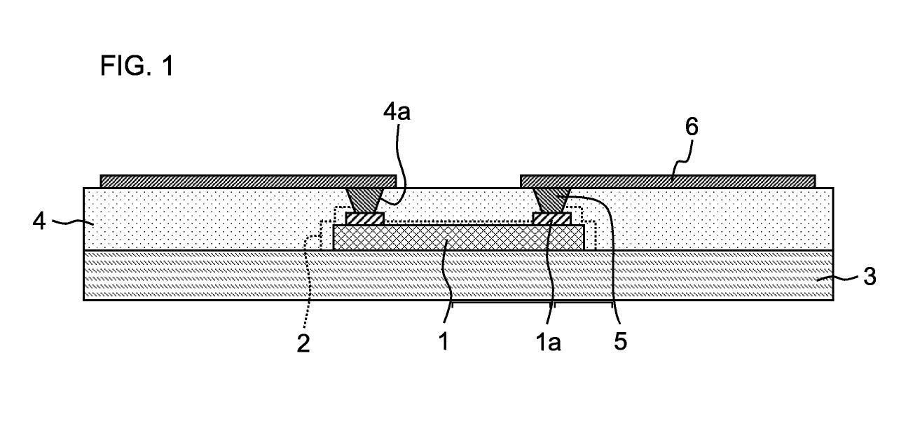

In a semiconductor device according to an exemplary embodiment of the present invention, a semiconductor chip (1 in FIG. 1) having external terminal(s) (1a in FIG. 1) is embedded in an insulating layer (4 in FIG. 1), and interconnect conductor(s) (6 in FIG. 1) are formed on the insulating layer. In this semiconductor device, base hole(s) (4a in FIG. 1) are formed at position(s) of the insulating layer corresponding to the external terminal(s) in a state where the semiconductor chip has shrunk after having been embedded in the insulating layer. The interconnect conductor(s) is (are) electrically connected to the external terminal(s) through the base hole(s).

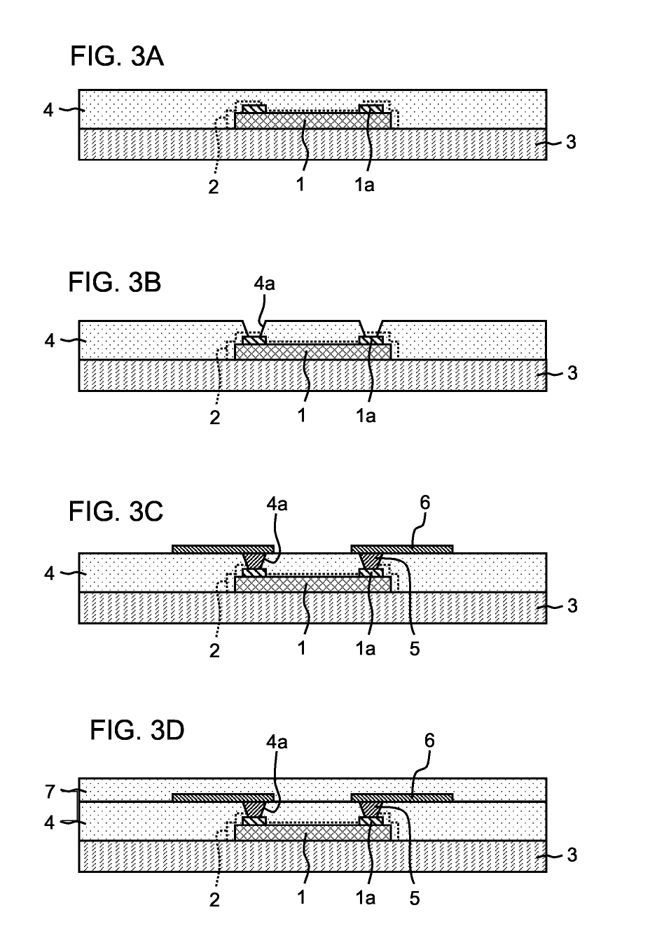

A semiconductor device manufacturing method according to an exemplary embodiment of the present invention is a manufacturing method of a semiconductor device in which a semiconductor chip (1 in FIG. 3C) having external terminal(s) (1a in FIG. 3C) is embedded in an insulating layer (4 in FIG. 3C) and interconnect conductor(s) (6 in FIG. 3C) are formed on the insulating layer. The method includes a step (shown in FIG. 3B) of forming base hole(s) (4a in FIG. 3B) leading to the external terminal(s) at position(s) of the insulating layer that have been corrected to correspond to the external terminal(s) in a state where the semiconductor chip has shrunk, after embedding the semiconductor chip in the insulating layer (after a step in FIG. 3A).

Reference symbols in drawings of the present application are assigned solely for facilitating understanding, and do not intend to limit the invention to modes shown in the drawings.

### FIRST EXAMPLE

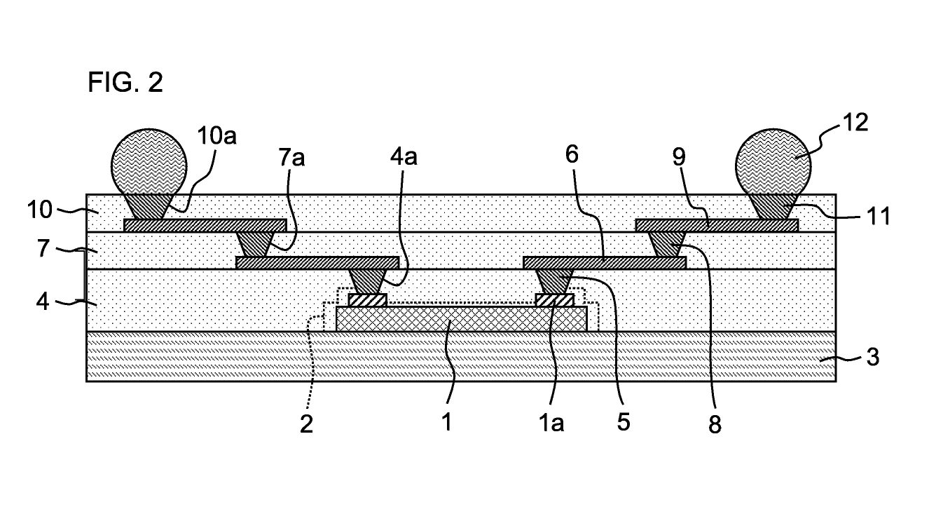

A semiconductor device according to a first example of the present invention will be described, using drawings. FIG. 1 is a sectional view schematically showing a configuration of the semiconductor device according to the first example of the present invention. FIG. 2 is a sectional view schematically showing a configuration of a variant of the semiconductor device according to the first example of the present invention.

Referring to FIG. 1, the semiconductor device according to the first example is a semiconductor device in which a semiconductor chip 1 having external terminal(s) 1a (pads) is embedded in an insulating layer 4, and interconnect conductor(s) 6 are formed on the insulating layer 4. Base hole(s) 4a leading to the external terminal(s) 1a are formed at position(s) of the insulating layer 4 corresponding to the external terminal(s) 1a in a state where the semiconductor chip 1 has shrunk after having been embedded in the insulating layer 4. The interconnect conductor(s) 6 are electrically connected to the external terminal(s) 1a through the base hole(s) 4a.

The semiconductor chip 1 is obtained by dividing a semiconductor on a wafer or the like including semiconductor elements collectively formed on the wafer into individual chips by dicing or the like. Generally, the semiconductor elements of an LSI or the like are collectively formed on the wafer. In the semiconductor chip 1, the semiconductor elements are formed on a semiconductor substrate, insulating layers and interconnect layers are alternately formed over the semiconductor substrate including the semiconductor elements, the semiconductor elements and a lowermost one of the interconnect layers are electrically connected through plugs, the interconnect layers are electrically connected through via interconnect(s), an insulator such as a solder resist is formed on one of the insulating layers including an uppermost one of the interconnect layers, base hole(s) leading to predetermined portions of the uppermost interconnect layer are formed in the insulator, and the external terminal(s) 1a are formed on the uppermost interconnect layer exposed from the base hole(s).

The external terminal(s) 1a are terminals formed on the periphery of a chip surface, for electrically connecting the semiconductor elements and an outside, and are also referred to as LSI pads or the like. Each external terminal 1a is connected to one of a power supply, ground, a signal, and the like. A material mainly formed of Al or Cu is often used for the external terminal 1a. The material for the external terminal 1a is not limited to these materials. It is a common practice to collectively form the external terminal(s) 1 on the wafer. The external terminal(s) 1a, however, can also be formed after dicing.

The semiconductor chip 1 is mounted on a support plate 3. The semiconductor chip 1 is embedded in the insulating layer 4. Immediately after the semiconductor chip 1 has been embedded in the insulating layer 4, the semiconductor chip 1 does not receive compressive stress like a semiconductor chip indicated by dotted lines (semiconductor chip 2 before shrinkage). However, when the semiconductor chip 1 is cooled, the semiconductor chip 1 receives the compressive stress and shrinks like the semiconductor chip 1 indicated by solid lines.

The term “embedded” herein means that the semiconductor chip 1 is buried in the insulating layer 4. In addition to a case where the semiconductor chip 1 is completely embedded, the term “embedded” may include a case where the semiconductor chip 1 is partly embedded, e.g. a case where a back face or an upper face of the semiconductor chip 1 is partly exposed.

Shrinkage of the semiconductor chip 1 with the compressive stress becomes particularly pronounced when the semiconductor chip 1 is thinned, and an effect of the present invention (effect that positional misalignment between the external terminal(s) 1a and the base hole(s) 4a can be eliminated) is especially increased when using the semiconductor chip that has been thinned. That is, when the semiconductor chip 1 is thin, stress per sectional area of each chip increases. Accordingly, shrinkage of the semiconductor chip 1 increases. Thus, there is a problem that degrees of shrinkage of the semiconductor chip 1 and positional deviations of the base hole(s) 4a (via interconnect(s) 5 or interconnect conductor(s) 6) due to the shrinkage of the semiconductor chip 1 increase. According to the first example, each base hole 41 is formed at the position corresponding to the external terminal la in the state where the semiconductor chip 1 has shrunk. Thus, the problem as described above can be solved. The reduced thickness of the semiconductor chip can be set to 50 μm or less. Preferably, the thickness of the semiconductor chip 1 is set to 30 μm or less. More preferably, the thickness of the semiconductor chip 1 is set to 10 μm or less. It is a common practice to reduce the thickness of the wafer by grinding a back face of the wafer (surface on the substrate side of the wafer) before the wafer is diced in order to obtain the semiconductor chip 1 with a reduced thickness. The thickness of the wafer may be reduced after the wafer has been diced.

When the thickness of the semiconductor chip 1 is thinner than that of the support plate 3, the effect of the present invention (effect that positional misalignment between the external terminal(s) 1a and the base hole(s) 4a can be eliminated) is particularly great. It is because of the following reason. As for shrinkage of the semiconductor chip 1, there is a problem that the semiconductor chip 1 shrinks due to stress from materials surrounding the semiconductor chip 1 including the support plate 3. In a case where the compression stress which will be applied for each chip sectional area is mainly caused by the support plate 3 made of a metal, the thicker the thickness of the support plate 3 is and the thinner the thickness of the semiconductor chip 1 is, the more compressive stress becomes, so that shrinkage of the semiconductor chip 1 increases. Especially when the thickness of the semiconductor chip 1 is smaller than half of the thickness of the support plate 3, the effect of the present invention is further great. When the thickness of the semiconductor chip 1 is smaller than one fifth of the thickness of the support plate 3, and is further smaller than one tenth of the thickness of the support plate 3, the effect of the present invention is great.

Though FIG. 1 shows an example where one semiconductor chip 1 is mounted, two or more of the semiconductor chips 1 may be mounted. In a case of a semiconductor device in which two or more of the semiconductor chips 1 are mounted, it becomes difficult to correct positional deviation of all the external terminal(s) 1a due to shrinkage of the semiconductor chips 1. Thus, the effect of the present invention (effect that positional misalignment between the external terminal(s) 1a and the base hole(s) 4a can be eliminated) is particularly great. “Mounting of two or more of the semiconductor chips 1” may include a case where one semiconductor device has two or more of the semiconductor chips 1, and may also include a case where a plurality of semiconductor devices each including one semiconductor chip 1 are in the form of a plate-like body, as in a plate-like body during a manufacturing process before the semiconductor devices (semiconductor packages) are separated into individual semiconductor devices.

The semiconductor chip 1 is fixed to the support plate 3 using an adhesive film such as a die attachment film or a chip bonding film, or a silver paste. Alternatively, the wafer (silicon) and the support plate 3 (metal) may be directly brought into contact to each other, thereby causing a joint between the silicon and the metal. Assume that the semiconductor chip 1 is fixed to the support plate 3 using the die attachment film or the like. Then, the thinner the die attachment film or the like that will be used is, the less there is a loss in transmission of stress between the semiconductor chip 1 and the support plate 3. That is, an effect of lessening stress is not effective. Thus, the effect of the present invention (effect that positional nonalignment between the external terminal(s) 1a and the base hole(s) 4a can be eliminated) is great. Further, when the wafer and the support plate are directly brought into contact with each other to cause the joint between the silicon and the metal, the effect of the present invention is the greatest. When mounting the semiconductor chip 1, the semiconductor chip 1 is disposed or arrayed on the support plate 3 in advance. In this case, the semiconductor chip 1 may be disposed with an active surface (surface on the side of the external terminal 1a) of the semiconductor chip 1 facing upward. Alternatively, the semiconductor chip 1 may be disposed on an insulating layer 4 prepared for in advance with the active surface facing downward. The effect of the present invention is particularly effective when a plurality of the semiconductor chips 1 are arranged on the support plate 3, and is particularly effective in manufacture of a semiconductor device including the support plate 3 in the course of manufacture, which is large and on which a large number of semiconductor chips are mounted.

A metal plate, a ceramic plate, a resin plate, or the like, for example, may be employed as the support plate 3. The support plate 3 may be an interconnect substrate formed of an insulating material and including an interconnect layer. With this arrangement, interconnects that conduct to both sides of the support plate 3 can be formed.

The larger an elastic modulus of the support plate 3 is, the more becomes the compressive stress which will be applied to the semiconductor chip. Accordingly, when the support plate 1 is formed of a metal or the like, the effect of the present invention (effect that positional nonalignment between the external terminal(s) 1a and the base hole(s) 4a can be eliminated) is great. As such a metal plate, a copper plate, an aluminum plate, an SUS plate, or an alloy plate formed of 42 alloy or the like can be enumerated.

The thickness of the support plate 3 is often thicker than the thickness of the insulating layer 4 in which the semiconductor chip 1 is embedded. Thus, the degree of compression of the semiconductor chip 1 in the insulating layer 4 (formed of a resin material, for example) increases. Accordingly, in view of this respect as well, the effect of the present invention (effect that positional misalignment between the external terminal(s) 1a and the base hole(s) 4a can be eliminated) is great.

Though the support plate 3 is illustrated in FIG. 1, this support plate 3 is not an essential requisite of the present invention. A metal such as copper or aluminum or a glass-reinforced resin material used as a material forming the support plate 3 often has an elastic modulus larger than the insulating layer (formed of the resin material, for example). Thus, the effect of causing the semiconductor chip 1 to shrink is great. Accordingly, the effect of the present invention (effect that positional misalignment between the external terminal(s) 1a and the base hole(s) 4a can be eliminated) is great in a semiconductor device including the support plate 3.

The insulating layer 4 is formed on the support plate 3 including the semiconductor chip 1, and the base hole(s) 4a is (are) formed at position(s) of the insulating layer 4 corresponding to the external terminal(s) 1a in the state where the semiconductor chip 1 has shrunk after having embedded in the insulating layer 4.

The insulating layer 4 functions to embed the semiconductor chip 1 therein. Any one of an inorganic material and an organic material may be employed for the insulating layer. Elastic moduluses of these materials are large. The larger thermal expansion coefficients of these materials are, the more becomes the compressive stress that will be applied to the semiconductor chip 1. The effect of the present invention is therefore important. As the organic material, the resin material is suitable, and any one of a non-photosensitive resin and a photosensitive resin can be used. Though both of a thermosetting resin and a thermoplastic resin are included in the resin material, the effect of the present invention is especially great when the thermoplastic resin of which shrinkage occurs during curing is used. The resin material may include an inorganic filler such as silica filler or an organic filler. The semiconductor chip 1 is readily embedded when the thermosetting resin is used for the insulating layer 4. As such a thermosetting resin, an epoxy resin, a polyimide resin, or the like can be pointed out. When using the thermosetting resin for the insulating layer 4, the following method can be pointed out for embedding the semiconductor chip 1: the semiconductor chip 1 is embedded while the thermosetting resin is in an uncured or semicured state, and then the thermosetting resin on which a heating process has been performed is fully cured. On the other hand, when using the thermoplastic resin for the insulating layer 4, the thermoplastic resin is softened in a heated state, and the semiconductor chip 1 can be thereupon embedded in the insulating layer 4. When the insulating layer 4 is formed, the insulating layer 4 undergoes the heating process. The support plate 3 made of the metal and the insulating layer 4 formed of the resin, for example, have different heat expansion coefficients. Further, when the thermosetting resin is used for the insulating layer 4, shrinkage occurs during curing of the insulating layer 4. Accordingly, even if the semiconductor device is manufactured, after passing through the heating process with no stress applied thereto, compressive stress acts on the semiconductor chip 1 after thermosetting due to a difference between heat expansion coefficients of the semiconductor chip 1 and the support plate 3 or the insulating layer 4. The semiconductor chip 1 is compressed, and positions of the external terminal(s) 1a of the semiconductor chip 1 change due to compression of the semiconductor chip 1. Thus, the effect of the present invention (effect that positional misalignment between the external terminal(s) 1a and the base hole(s) 4a can be eliminated) is especially great.

The base hole(s) 4a can also be formed by laser radiation or the like when the insulation material is the non-photosensitive resin. Alternatively, the base hole(s) 4a can be formed by drilling. On the other hand, in a case where the material for the insulating layer 4 is the photosensitive resin, the base hole(s) 4a can be formed by exposure and development processes.

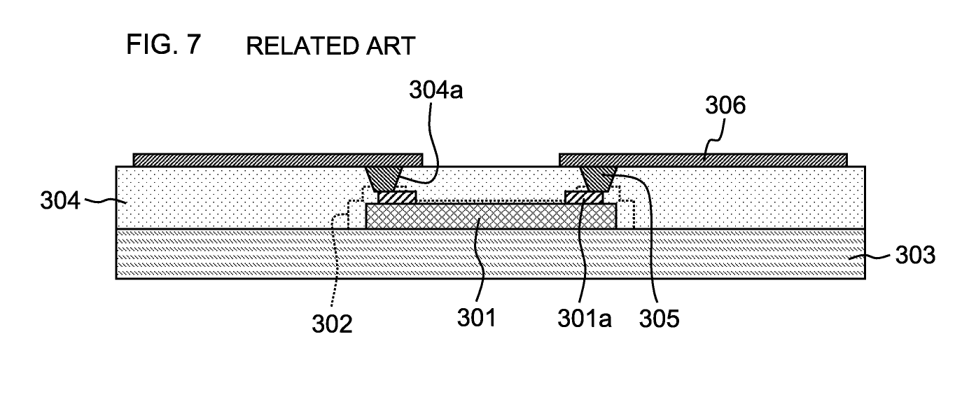

In a semiconductor device (refer to FIG. 7) according to related art 3, a semiconductor chip 301 shrinks due to stress generated by shrinkage of a support plate 303 formed of a resin material, a metal, or the like which supports the semiconductor chip 301 having a large heat expansion coefficient. Accordingly, misalignment between positions of external terminal(s) 301a and base hole(s) 304a (via interconnect(s) 305 or interconnect conductor(s) 306) occurs. A connection failure may be generated, or reliability may be impaired.

In contrast therewith, in the semiconductor device according to the first example (refer to FIG. 1), by correcting positions where the base hole(s) 4a (via interconnect(s) 5 or interconnect conductor(s) 6) are formed in view of shrinkage of the chip or the like, positions of the external terminal(s) 1a and the base hole(s) 4a (via interconnect(s) 5 or interconnect conductor(s) 6) can be aligned with high accuracy.

Each via interconnect 5 is an interconnect made of a conductive material embedded into the base hole 4a on a corresponding one of the external terminal(s) 1a of the semiconductor chip 1. The via interconnect 5 can be formed by a method of printing a conductive paste (such as a metal paste) or a metal powder. The via interconnect 5 may be unitarily formed with the interconnect conductor 6. The via interconnect 5 may be filled in the base hole 4a. Alternatively, the via interconnect 5 may be formed on a side wall of the base hole 4a and a surface of the external terminal la to a predetermined thickness, not being filled in the base hole 4a.

The interconnect conductor(s) 6 are formed on the insulating layer 4 including the via interconnect(s) 5 in a predetermined shape. Each interconnect conductor 6 is electrically connected to a corresponding one of the external terminal(s) 1a through a corresponding one of the base hole(s) 4a. Referring to FIG. 1, the interconnect 6 is electrically connected to the external terminal 1a through the via interconnect (conductor) 5 embedded in the base hole 4a. The interconnect conductor 6 and the via interconnect 5 may be unitarily formed, thereby directly connecting the interconnect conductor 6 and the external terminal 1a. The interconnect conductor 6 may be formed of a single layer or a plurality of layers.

FIG. 1 shows an example where the interconnect conductor 6 is formed of one layer alone. Positional misalignment between the external terminal(s) 1a and the base hole(s) 4a (via interconnect(s) 5 or wiring conductors 6) or the like due to shrinkage of the semiconductor chip often occurs in the vicinity of the semiconductor chip 1 where the external terminal(s) 1a are arranged at narrow pitches. Accordingly, in order to facilitate understanding of this phenomenon, the interconnect conductor 6 is shown as being formed of one layer. The semiconductor device of the present invention, however, is not limited to the case where the interconnect conductor 6 is formed of one layer, and may be configured to be of a multi-layer interconnect structure, as shown in FIG. 2. When the interconnect conductor(s) 6 and interconnect conductor(s) 9 are formed of a plurality of layers as shown in FIG. 2, these interconnect conductors 6 and 9 are mutually connected through via interconnect(s) 8.

The interconnect conductor(s) 6 can be formed by plating the via interconnect(s) 5 and the insulating layer 4 exposed from blank portions of a predetermined pattern of a plating resist (by a metal) after the predetermined pattern of the plating resist has been formed on the insulating layer 4, and then stripping off the plating resist, for example. Any one of a varnish resist layer and a film-like resist may be used as the plating resist. To take an example, a negative-type photoresist whose solubility for a developing solution decreases due to exposure may be employed. Alternatively, a positive-type photoresist whose solubility for the developing solution increases due to the exposure may also be employed. A light source such as a halogen lamp can be employed as a light source to be used for exposure. A laser light source or the like may also be employed. When a seed layer is necessary in the plating process, the seed layer is formed before formation of the plating resist. Then, the seed layer is removed after the plating resist has been stripped off. The seed layer may be formed by sputtering or the like. The seed layer may also be formed by electroless plating. In addition to that, the interconnect conductor(s) 6 can be formed by a method of printing a metal paste or a metal powder.

An insulating layer 7 in FIG. 2 can be configured to be similar to the insulating layer 4. Each base hole 7a formed in the insulating layer 7 to lead to the interconnect conductor 6 can be configured to be similar to the base hole 4a. A via interconnect 8 embedded in each base hole 7a on the interconnect conductor 6 can be configured to be similar to the via interconnect 5. Each interconnect conductor 9 formed on the insulating layer 7 including the via interconnect(s) 5 can be configured to be similar to each interconnect conductor 6. The interconnect conductor(s) 9 can be integrally formed with the via interconnect(s) 8. An insulating layer 10 formed of a solder resist or the like may be formed over the insulating layer 7 including the interconnect conductor(s) 9 as an uppermost layer. Each base hole 10a formed in the insulating layer 10 to lead to the interconnect 9 can be configured to be similar to the base hole 4a. An electrode pad 11 on the interconnect conductor 9 that has been embedded in each base hole 10a can be configured to be similar to the via interconnect 5. A solder is used for each solder bump 12 formed on the electrode pad 11.

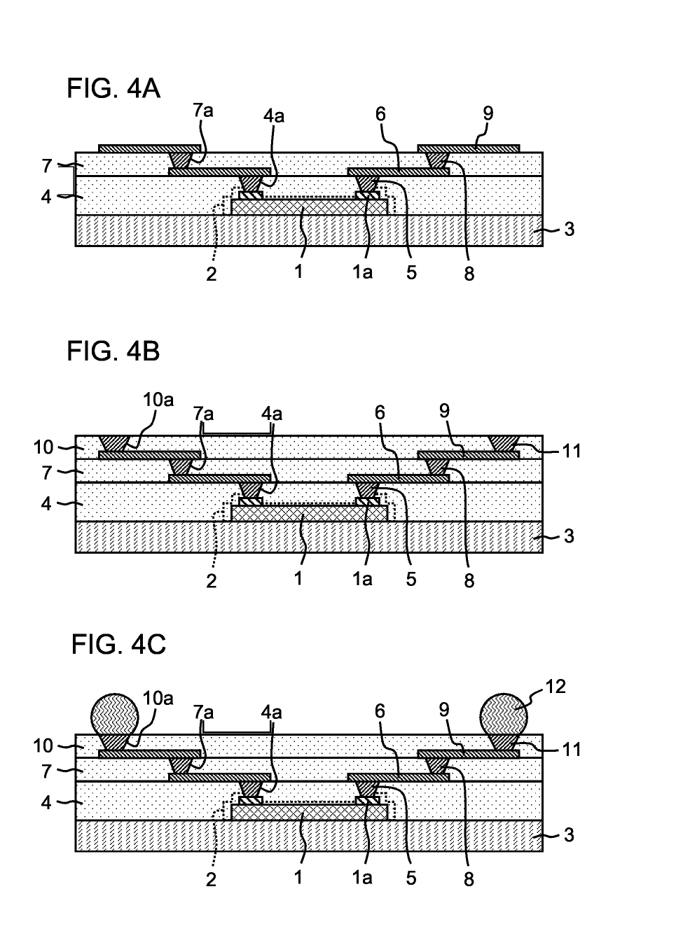

Next, a method of manufacturing a variant (refer to FIG. 2) of the semiconductor device according to the first example of the present invention will be described using drawings. FIGS. 3A to 4C are sectional views of steps schematically showing the method of manufacturing the variant of the semiconductor device according to the first example of the present invention.

First, a semiconductor chip that has been thinned and obtained by diving into individual chips (corresponding to the semiconductor chip 2 before shrinkage) is mounted on the support plate 3 with the external terminal(s) 1a facing upward (to a side opposite to the support plate 3). Then, the insulating layer 4 is formed over the support plate 3 including the semiconductor chip 2, thereby embedding the semiconductor chip 2 in the insulating layer 4 (in step A1: refer to FIG. 3A).

A copper plate of a 100 mm square (with a thickness of 0.5 mm) can be herein used as the support plate 3. An LSI chip having a chip size of 8 mm, a chip thickness of 50 μm, a pad pitch of 80 μm and a pad size of 30 μmφ can be used as the semiconductor chip 2. A lot of the semiconductor chips 2 can be mounted at pitches of 30 mm. When mounting the semiconductor chip 2, a die bonding tape (double-sided tape) can be attached to the back face of the semiconductor chip 2, thereby adhering the semiconductor chip 2 to the support plate 3. The insulating layer 4 can be formed by laminating semi-cured thermosetting epoxy resin films (each of which has a thickness of 90 μm and is opaque) to embed the semiconductor chip 2 in the insulating layer 4, removing a resin of positioning marker portion(s) for a laser on the periphery of the semiconductor chip, and then curing the thermosetting epoxy resin films. When the semiconductor chip in a stage after step A1 has been observed by an X-ray inspection apparatus, it can be confirmed that the semiconductor chip 1 has been obtained by shrinkage and positions of the external terminal(s) 1a on the semiconductor chip 1 have deviated due to shrinkage, compared with a state before the shrinkage.

Next, the base hole(s) 4a leading to the external terminal(s) 1a are formed at position(s) of the insulating layer 4 that have been corrected to correspond to the external terminal(s) 1a in a state where the semiconductor chip 1 has obtained by shrinkage (in step A2: refer to FIG. 3B).

The base hole(s) 4a can be formed by the laser or the like. When forming the base hole(s) 4a, a value of positional deviation of each external terminal 1a on the semiconductor chip 1 due to the shrinkage is input to laser process data as a correction value, thereby forming the base hole(s) 4a. The size of each base hole 4a can be set to 20 μmφ. When the position(s) of the external terminal(s) 1a and the positions of the base hole(s) 4a have been observed in a stage after step A2, using the X-ray inspection device, it is seen that almost all the base hole(s) 4a have been formed at the centers of the external terminal(s) 1a.

Next, the via interconnect (conductor) 5 is embedded in each base hole 4a, and the interconnect conductor(s) 6 are formed on the insulating layer 4 including the via interconnect(s) 5 (in step A3; refer to FIG. 3C).

The via interconnect(s) 5 and the interconnect conductor(s) 6 can be formed by plating using a plating resist. The plating resist can be formed by performing exposure using an exposure mask designed using the positional deviation of each external terminal 1a on the semiconductor chip 1 due to the shrinkage as the correction value and then performing development. By performing plating using the plating resist as a mask, the via interconnect(s) 5 and the interconnect conductor(s) 6 can be fabricated. The via interconnect(s) 5 and the interconnect conductor(s) 6 can be formed by a semi-additive method in which using the seed layer formed through electroless plating after a desmear process, a pattern is formed on the plating resist that has been applied, using this exposure mask. When the via interconnect(s) 5 and the interconnect conductor(s) 6 have been observed in a stage after step S3, it is seen that the fabricated via interconnect(s) 5 and the interconnect conductor(s) 6 also have been properly formed, corresponding to the base hole(s) 4a.

Next, the insulating layer 7 is formed over the insulating layer 4 including the interconnect conductor(s) 6 (in step A4; FIG. 3D).

Next, the base hole(s) 7a leading to the interconnect conductor(s) 6 are formed in the insulating layer 7, and the via interconnect(s) (conductors) 8 are respectively embedded in the base hole(s) 7a. Then, interconnect conductor(s) 9 are formed on the insulating layer 7 including the via interconnect(s) 8 (in step A5; refer to FIG. 4A).

Next, an insulating layer 10 is formed over the insulating layer 7 including the interconnect conductor(s) 9. The base hole(s) 10a leading to the interconnect conductor(s) 9 are formed in the insulating layer 10, and the electrode pads (conductor) 11 are embedded in the base hole(s) 10a (in step A6; refer to FIG. 4B).

Finally, a solder bump 12 for connection to an outside is formed on each electrode pad 11 (in step A7; refer to FIG. 4C).

FIGS. 3A to 4C show a method of manufacturing the semiconductor device including the support plate 3. The support plate 3 may be removed after step A3 (refer to FIG. 3C). When the support plate 3 is removed after step A3, for example, there remains only the insulating layer 4 including the semiconductor chip 1, the via interconnect(s) 5, and the interconnect conductor(s) 6. With this arrangement, electrical connection or the like can be made from the side of the semiconductor device where the support plate 3 is mounted. The semiconductor device in which connection can be made from upper and lower surfaces of the semiconductor device in the form of a plate-like body can be obtained. Herein, removal of the support plate 3 means elimination of the support plate 3. As a method of this removal, removal of the support body 3 by metal etching or the like, removal of the support body 3 by a solvent or the like, removal of the support body 3 by peeling off, and the like may be pointed out.

A semiconductor device, as a comparative example, was fabricated without using a position deviation of each external terminal 301a on a semiconductor chip 301 due to shrinkage as a correction value for laser process data and mask design, as shown in related-art example 3 (refer to FIG. 7). Then, when the bottom of each base hole 304a after the laser process was observed, there were locations in the semiconductor device where only a portion of the external terminal 301a could be seen through the bottom of the base hole 304a and the external terminal 301a could not be seen through the bottom of the base hole 304a. Further, when a relationship among positions of the external terminal(s) 301a, the base hole(s) 304a, via interconnect(s) 305, and interconnect conductor(s) 306 was observed by a X-ray inspection apparatus, positional misalignment between the external terminal(s) 301a and the base hole(s) 304a considered to be caused by shrinkage about the semiconductor chip 301 was recognized, though the positions of the base hole(s) 304a, the via interconnect(s) 305, and the interconnect conductor(s) 306 were properly aligned.

According to the first example, the positions of the external terminal(s) (pads) 1a and the via interconnect(s) 5 (or interconnect conductor(s) 6) are properly aligned in the semiconductor device. Thus, the semiconductor chip 1 with narrow-pitched terminals can be embedded. Further, connections between the external terminal(s) 1a and the via interconnect(s) 5 (or interconnect conductor(s) 6) become strong. Accordingly, the semiconductor device with excellent reliability can be obtained. Still further, even in the semiconductor chip 1 including the external terminal(s) 1a that are arranged at narrow pitches, the external terminal(s) 1a can be securely connected to the via interconnect(s) 5 (or interconnect conductor(s) 6). Further, positional deviations between the external terminal(s) 1a and the base hole(s) 4a (via interconnect(s) 5 or interconnect conductor(s) 6) can be reduced. Thus, the semiconductor device can be manufactured with a high yield. After the semiconductor has been manufactured, connections between the external terminal(s) 1a and the via interconnect(s) 5 (or interconnect conductor(s) 6) are satisfactory. Thus, the semiconductor device with excellent reliability can be obtained in which no fault will occur during a temperature cycle test.

Modifications and adjustments of an exemplary embodiment and an example are possible within the scope of the overall disclosure (including claims) of the present invention, and based on the basic technical concept of the invention. Various combinations and selections of various disclosed elements are possible within the scope of the claims of the present invention. That is, the present invention of course includes various variations and modifications that could be made by those skilled in the art according to the overall disclosure including the claims and the technical concept.

### INDUSTRIAL APPLICABILITY

As an application example of the present invention, a semiconductor device including a semiconductor chip having a plurality of external terminal(s) embedded in a substrate thereof, which is used for a cellular phone, electrical equipment, or the like, can be pointed out.

What is claimed is:

1. A semiconductor device with a semiconductor chip embedded in an insulating layer thereof and with interconnect conductor(s) formed on the insulating layer thereof, the semiconductor chip including external terminal(s), wherein
base hole(s) is (are) formed at position(s) of the insulating layer corresponding to the external terminal(s) in a state where the semiconductor chip has shrunk after having been embedded in the insulating layer; and
the interconnect conductor(s) is (are) electrically connected to the external terminal(s) through the base hole(s).

2. The semiconductor device according to claim 1, wherein
the interconnect conductor(s) is (are) formed to correspond to the external terminal(s) in the state where the semiconductor chip has shrunk after having been embedded in the insulating layer, and are electrically connected to the external terminal(s) through via interconnect(s) embedded in the base hole(s).

3. The semiconductor device according to claim 1, wherein
the interconnect conductor(s) is (are) formed to correspond to the external terminal(s) in the state where the semiconductor chip has shrunk after having been embedded in the insulating layer, and are directly connected to the external terminal(s) through the base hole(s).

4. The semiconductor device according to claim 1, wherein the semiconductor chip has a thickness of 50 m or less.

5. The semiconductor device according to claim 1, wherein
the semiconductor chip is mounted on a support plate; and
the insulating layer is formed over the support plate including the semiconductor chip, thereby embedding the semiconductor chip therein.

6. The semiconductor device according to claim 5, wherein the support plate is a metal plate.

7. The semiconductor device according to claim 5, wherein the semiconductor chip has a thickness thinner than the support plate.

8. The semiconductor device according to claim 1, wherein the insulating layer is formed of a resin.

9. The semiconductor device according to claim 8, wherein the resin is a thermosetting resin.

10. The semiconductor device according to claim 1, wherein the semiconductor chip comprises a plurality of semiconductor chips.

11. The semiconductor device according to claim 5, wherein the support plate has a heat expansion coefficient larger than that of the semiconductor chip.

12. The semiconductor device according to claim 1, wherein the insulating layer has a heat expansion coefficient larger than that of the semiconductor chip.

13. A method of manufacturing a semiconductor device with a semiconductor chip embedded in an insulating layer thereof and with interconnect conductor(s) formed on the insulating layer thereof, the semiconductor chip comprising external terminal(s), the method comprising:
after embedding the semiconductor chip in the insulating layer, forming base hole(s) leading to the external terminal(s) at position(s) of the insulating layer that has (have) been corrected to correspond to the external terminal(s) in a state where the semiconductor chip has shrunk.

14. The method of manufacturing a semiconductor device according to claim 13, comprising:
after forming the base hole(s), embedding via interconnect(s) in the base hole(s); and
forming on the insulating layer including the via interconnect(s) the interconnect conductor(s) that has (have) been corrected to correspond to the external terminal(s) in the state where the semiconductor chip has shrunk.

15. The method of manufacturing a semiconductor device according to claim 13, comprising:
after forming the base hole(s), forming on the insulating layer including the base hole(s) and the external terminal(s) the interconnect conductor(s) that has (have) been corrected to correspond to the external terminal(s) in the state where the semiconductor chip has shrunk.

16. The method of manufacturing a semiconductor device according to claim 13, comprising the steps of:
before forming the base hole(s),
mounting the semiconductor chip on a support plate; and
forming the insulating layer over the support plate including the semiconductor chip after mounting the semiconductor chip, thereby embedding the semiconductor chip in the insulating layer.

17. The method of manufacturing a semiconductor device according to claim 14, comprising:
removing the support plate after forming the interconnect conductor(s).
